(19) United States
(12) Patent Application Publication
(10) Pub. No.: US 2025/0048805 A1
(43) Pub. Date: Feb. 6, 2025

(54) LIGHT EMITTING ELEMENT, MANUFACTURING METHOD OF LIGHT EMITTING ELEMENT, DISPLAY DEVICE INCLUDING LIGHT EMITTING ELEMENT, AND MANUFACTURING METHOD OF DISPLAY DEVICE

(71) Applicant: Samsung Display Co., LTD., Yongin-si (KR)

(72) Inventors: Won Ho LEE, Yongin-si (KR); Jong Hyuk KANG, Yongin-si (KR); Buem Joon KIM, Yongin-si (KR); Hyun Deok IM, Yongin-si (KR)

(73) Assignee: Samsung Display Co., LTD., Yongin-si (KR)

(21) Appl. No.: 18/599,059

(22) Filed: Mar. 7, 2024

(30) Foreign Application Priority Data
Jul. 31, 2023 (KR) 10-2023-0099988

(51) Int. Cl. H01L 33/56; H01L 25/075; H01L 33/00

(52) U.S. Cl. CPC H01L 33/56; H01L 25/0753; H01L 33/0095

(57) ABSTRACT

A light emitting element, a manufacturing method of the light emitting element, a display device including the light emitting element, and a manufacturing method of the display device are provided. The light emitting element includes end portions including a first end portion and a second end portion; a side portion between the first end portion and the second end portion; a semiconductor stacked member including a first semiconductor layer adjacent to the first end portion, a second semiconductor layer adjacent to the second end portion, and an active layer between the first semiconductor layer and the second semiconductor layer; a first surface member on the side portion and having a first surface energy; and a second surface member on the end portions and having a second surface energy less than the first surface energy.

### CROSS-REFERENCE TO RELATED APPLICATION(S)

This application claims priority to and benefits of Korean patent application No. 10-2023-0099988 under 35 U.S.C. § 119, filed on Jul. 31, 2023, in the Korean Intellectual Property Office, the entire contents of which are incorporated herein by reference.

### BACKGROUND

### 1. Technical Field

The disclosure relates to a light emitting element, a manufacturing method of the light emitting element, a display device including the light emitting element, and a manufacturing method of the display device.

### 2. Description of the Related Art

Recently, as interest in information display is increasing, research and development on display devices are continuously made.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure describes a light emitting element, a manufacturing method of the light emitting element, a display device including the light emitting element, and a manufacturing method of the display device, in which a degree of alignment of the light emitting elements can be improved.

The disclosure describes a light emitting element, a manufacturing method of the light emitting element, a display device including the light emitting element, and a manufacturing method of the display device, in which a risk of abnormal alignment of the light emitting elements can be reduced and the light emitting elements can thus operate normally.

A light emitting element according to an embodiment may include end portions including a first end portion and a second end portion; a side portion disposed between the first end portion and the second end portion; a semiconductor stacked member including a first semiconductor layer adjacent to the first end portion, a second semiconductor layer adjacent to the second end portion, and an active layer disposed between the first semiconductor layer and the second semiconductor layer; a first surface member disposed on the side portion, the first surface member having a first surface energy; and a second surface member disposed on the end portions, the second surface member having a second surface energy less than the first surface energy of the first surface member.

According to the embodiment, each of the first surface member and the second surface member may include at least one material selected from the group consisting of a silane material, a phosphonate material, a carboxylate material, a catechol material, an alkyne material, an alkene material, and an amine material. The first surface member may include a first functional group. The second surface member may include a second functional group different from the first functional group.

According to the embodiment, the first functional group may include one of a hydroxyl group (—OH) and a carboxyl group (—COOH).

According to the embodiment, the second functional group may include one of a methyl group (—CH3) and a fluorine group (—F).

According to the embodiment, the light emitting element may further include an insulating layer disposed on the semiconductor stacked member. The first surface member may be disposed on the insulating layer.

According to the embodiment, the light emitting element may further include an electrode layer adjacent to the second end portion and disposed on the second semiconductor layer. The second surface member may include a (2-1) surface member disposed at the first end portion and a (2-2) surface member disposed at the second end portion. The (2-1) surface member may be disposed on the first semiconductor layer. The (2-2) surface member may be disposed on the electrode layer.

According to the embodiment, the (2-1) surface member and the (2-2) surface member may include a same material.

According to the embodiment, the (2-1) surface member and the (2-2) surface member may include different materials.

According to the embodiment, each of the first surface member and the second surface member may include molecular assemblies, and the molecular assemblies may form a surface treatment structure on an outer surface of the light emitting element.

According to the embodiment, a number of the molecular assemblies forming the second surface member per unit area on which the second surface member is disposed may be greater than a number of the molecular assemblies forming the first surface member per unit area on which the first surface member is disposed.

A manufacturing method of a light emitting element according to an embodiment may include patterning a semiconductor stacked member including a first semiconductor layer, a second semiconductor layer, and an active layer disposed between the first semiconductor layer and the second semiconductor layer on a growth substrate; and separating a light emitting element including the semiconductor stacking member from the growth substrate. The manufacturing method may further include performing a surface treatment on the light emitting element before the separating of the light emitting element including the semiconductor stacked member from the growth substrate; and performing an additional surface treatment on the light emitting element after the separating of the light emitting element including the semiconductor stacked member from the growth substrate.

According to the embodiment, the manufacturing method may further include patterning an electrode layer on an upper surface of the semiconductor stacked member; and patterning an insulating layer on a side surface of the semiconductor stacked member.

According to the embodiment, the manufacturing method may further include patterning a capping layer exposing the insulating layer. The patterning of the capping layer may be performed before the performing of the surface treatment.

According to the embodiment, the performing of the surface treatment may include forming a first surface member on the insulating layer. The performing of the additional surface treatment may include forming a second surface member at both end portions of the light emitting element. The second surface member may have a lower surface energy than a surface energy of the first surface member.

According to the embodiment, the manufacturing method may further include patterning a capping layer exposing the electrode layer. The patterning of the capping layer may be performed before the performing of the surface treatment.

According to the embodiment, the performing of the additional surface treatment may include forming a (2-1) surface member on the first semiconductor layer. The performing of the surface treatment may include forming a (2-2) surface member on the electrode layer.

A display device according to an embodiment may include a first electrode and a second electrode disposed on a base layer; and light emitting elements aligned between the first electrode and the second electrode. Each of the light emitting elements may include end portions including a first end portion and a second end portion; a side portion between the first end portion and the second end portion; a semiconductor stacked member including a first semiconductor layer adjacent to the first end portion, a second semiconductor layer adjacent to the second end portion, and an active layer disposed between the first semiconductor layer and the second semiconductor layer; a first surface member disposed on the side portion of each of the light emitting elements, the first surface member having a first surface energy; and a second surface member disposed on the end portions of each of the light emitting elements, the second surface member having a second surface energy less than the first surface energy of the first surface member.

According to the embodiment, the second surface member may include a (2-1) surface member adjacent to the first end portion and a (2-2) surface member adjacent to the second end portion. A direction from the (2-1) surface member to the (2-2) surface member may be a same as a direction in which the first electrode and the second electrode are spaced apart from each other.

A manufacturing method of a display device according to an embodiment may include patterning an alignment electrode including a first alignment electrode and a second alignment electrode on a base layer; supplying ink including light emitting elements on the base layer; and aligning the light emitting elements between the first alignment electrode and the second alignment electrode. Each of the light emitting elements may include end portions including a first end portion and a second end portion; a side portion disposed between the first end portion and the second end portion; a semiconductor stacked member including a first semiconductor layer adjacent to the first end portion, a second semiconductor layer adjacent to the second end portion, and an active layer disposed between the first semiconductor layer and the second semiconductor layer; a first surface member disposed on the side portion of the light emitting elements, the first surface member having a first surface energy; and a second surface member disposed on the end portions of each of the light emitting elements, the second surface member having a second surface energy less than the first surface energy of the first surface member.

According to the embodiment, each of the first surface member and the second surface member may include at least one material selected from a group consisting of a silane material, a phosphonate material, a carboxylate material, a catechol material, an alkyne material, an alkene material, and an amine material. The first surface member may include a first functional group. The second surface member may include a second functional group different from the first functional group. The first functional group may include one of a hydroxyl group (—OH) and a carboxyl group (—COOH). The second functional group may include one of a methyl group (—CH3) and a fluorine group (—F).

According to embodiments, a light emitting element, a manufacturing method of the light emitting element, a display device including the light emitting element, and a manufacturing method of the display device, in which a degree of alignment of the light emitting elements can be improved can be provided.

According to an embodiment, a light emitting element, a manufacturing method of the light emitting element, a display device including the light emitting element, and a manufacturing method of the display device, in which a risk of abnormal alignment of the light emitting elements can be reduced and the light emitting elements can thus operate normally may be provided.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a light emitting element according to an embodiment.

FIG. 2 is a schematic cross-sectional view illustrating a light emitting element according to an embodiment.

FIG. 3 is a schematic plan view illustrating a display device according to an embodiment.

FIG. 4. is a schematic cross-sectional view illustrating a display device according to an embodiment.

FIGS. 5 and 6 are schematic drawings for illustrating a pixel according to an embodiment.

FIGS. 7 and 8 are schematic drawings illustrating a light emitting element including a surface member according to an embodiment.

FIGS. 9 to 20 are schematic drawings illustrating each process step of a manufacturing method of a light emitting element according to an embodiment.

FIG. 21 is a flowchart illustrating a manufacturing method of a display device according to an embodiment.

FIGS. 22 to 24 are schematic plan views illustrating each process step of a manufacturing method of a display device according to an embodiment.

FIGS. 25 to 27 are schematic cross-sectional views illustrating each process step of a manufacturing method of a display device according to an embodiment.

### DETAILED DESCRIPTION OF THE EMBODIMENTS

It will be apparent to those skilled in the art that various modifications and variations can be made in the disclosure without departing from the spirit or scope of the disclosure, and embodiments are illustrated in the drawings and explained in the detailed description. Thus, it is intended that the disclosure covers the modifications and variations within the scope of the disclosure and their equivalents.

In the drawings, sizes, thicknesses, ratios, and dimensions of the elements may be exaggerated for ease of description and for clarity. Like numbers refer to like elements throughout.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

As used herein, the singular forms, “a,” “an,” and “the” are intended to include the plural forms as well, unless the context clearly indicates otherwise.

In the specification, the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be further understood that when an element such as a layer, film, area, or substrate is referred to as being “on” another element, it can be directly on the other element or intervening elements may also be present. In the specification, it will be understood that when an element such as a layer, film, area, or substrate is referred to as being disposed “on” another element, the disposed direction is not limited to an upper direction and include a side portion direction or a lower direction. In contrast, It will be understood that when an element such as a layer, film, area, or substrate is referred to as being “beneath” another element, it can be directly beneath the other element or intervening elements may also be present.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

The disclosure relates to a light emitting element, a manufacturing method of the light emitting element, a display device including the light emitting element, and a manufacturing method of the display device. Hereinafter, a light emitting element, a manufacturing method of a light emitting element, a display device including a light emitting element, and a manufacturing method of the display device according to an embodiment will be described with reference to the accompanying drawings.

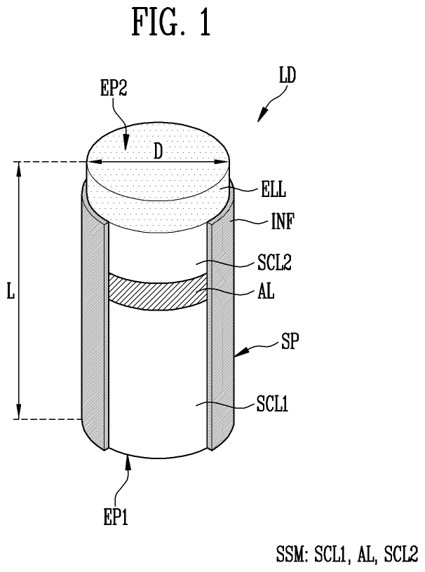

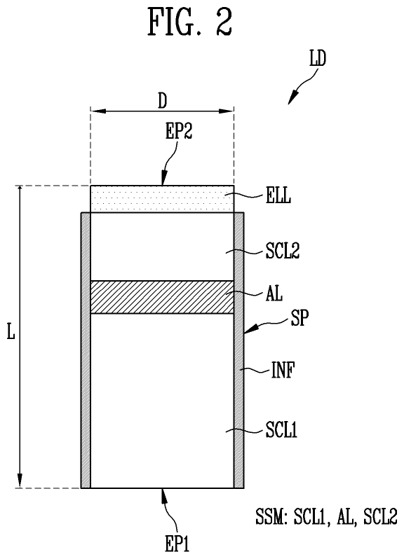

A light emitting element LD according to an embodiment will be described with reference to FIGS. 1 and 2. FIG. 1 is a schematic perspective view illustrating a light emitting element according to an embodiment. FIG. 2 is a schematic cross-sectional view illustrating a light emitting element according to an embodiment.

The light emitting element LD may emit light. The light emitting element LD may include a semiconductor stacked member SSM. According to the embodiment, the light emitting element LD may further include an electrode layer ELL and an insulating layer INF.

The semiconductor stacked member SSM may include a first semiconductor layer SCL1, a second semiconductor layer SCL2, and an active layer AL disposed between the first semiconductor layer SCL1 and the second semiconductor layer SCL2.

According to an embodiment, the first semiconductor layer SCL1, the active layer AL, and the second semiconductor layer SCL2 may be sequentially stacked in a length direction L of the light emitting element LD.

The light emitting element LD may include end portions EP1 and EP2 and a side portion SP.

According to the embodiment, the first semiconductor layer SCL1 may be adjacent to the first end portion EP1. The second semiconductor layer SCL2 may be adjacent to the second end portion EP2. According to the embodiment, the electrode layer ELL may be adjacent to the second end portion EP2.

According to the embodiment, the side portion SP may be formed between the first end portion EP1 and the second end portion EP2. According to the embodiment, the side portion SP may extend in the length direction L of the light emitting element LD.

According to the embodiment, the side portion SP may include a portion of a remaining area other than upper and lower surfaces of an object (for example, a semiconductor stacked member SSM, an active layer AL, a first semiconductor layer SCL1, or a second semiconductor layer SCL2, etc.). Here, the upper and lower surfaces of the object may refer to surfaces corresponding to the first end portion EP1 or the second end portion EP2 of the light emitting element LD.

According to the embodiment, the side portion SP may refer to (or include) a portion of an outer surface of the object defined in an area between the first end portion EP1 and the second end portion EP2 of the light emitting element LD.

The light emitting element LD may have various shapes. For example, the light emitting element LD may have a pillar shape extending in one direction or a direction. The pillar shape may include a rod-like shape or a bar-like shape that is long in the length direction L (for example, with an aspect ratio greater than 1), such as a circular pillar or a polygonal pillar. However, the disclosure is not limited thereto.

The light emitting element LD may have various sizes. For example, the light emitting element LD may have a size ranging from nanoscale to microscale. For example, each of a diameter D (or width) of the light emitting element LD and a length L of the light emitting element LD may have nanoscale or microscale. However, the disclosure is not limited thereto.

The first semiconductor layer SCL1 may include a semiconductor of a first conductive type. The first semiconductor layer SCL1 may be disposed on the active layer AL and may include a different type of semiconductor layer from the second semiconductor layer SCL2. For example, the first semiconductor layer SCL1 may include an N-type semiconductor layer. For example, the first semiconductor layer SCL1 may include at least one selected from the group consisting of InAlGaN, GaN, AlGaN, InGaN, AlN, and InN, and may include a N-type semiconductor layer doped with a first conductive dopant such as Si, Ge, Sn, and the like within the spirit and the scope of the disclosure. However, the disclosure is not limited to the examples described above. The first semiconductor layer SCL1 may include various materials.

The active layer AL may be disposed between the second semiconductor layer SCL2 and the first semiconductor layer SCL1. The active layer AL may include a single-quantum well or multi-quantum well structure. A position of the active layer AL is not limited to a specific example and may vary depending on a type of the light emitting element LD.

A clad layer doped with a conductive dopant may be formed on one side portion or a side portion and/or the other side portion or another side portion of the active layer AL. For example, the clad layer may include one or more of AlGaN and InAlGaN. However, the disclosure is not limited to the examples described above.

The second semiconductor layer SCL2 may include a semiconductor of a second conductive type. The second semiconductor layer SCL2 may be disposed on the active layer AL and may include a different type of semiconductor layer from the first semiconductor layer SCL1. For example, the second semiconductor layer SCL2 may include a P-type semiconductor layer. For example, the second semiconductor layer SCL2 may include at least one semiconductor materials selected from the group consisting of InAlGaN, GaN, AlGaN, InGaN, AlN, and InN, and may include a P-type semiconductor layer doped with a second conductive dopant such as Ga, B, Mg, and the like within the spirit and the scope of the disclosure. However, the disclosure is not limited to the examples described above. The second semiconductor layer SCL2 may include various materials.

In case that a voltage higher than a threshold voltage is applied to the first end portion EP1 and the second end portion EP2 of the light emitting element LD, electron-hole pairs may recombine with each other in the active layer AL, and the light emitting element LD can emit light. By controlling light emitting of the light emitting element LD using this principle, the light emitting element LD can be used as a light source in various devices.

The insulating film INF may be disposed on the outer surface of the semiconductor stacked member SSM. The insulating film INF may surround an outer surface of the active layer AL and may further surround a portion of each of the first semiconductor layer SCL1 and the second semiconductor layer SCL2. The insulating film INF may have a single-layer or multi-layer structure.

The insulating film INF may expose the first end portion EP1 and the second end portion EP2 of the light emitting element LD having different polarities. For example, the insulating film INF may expose an end portion of each of the electrode layer ELL and the first semiconductor layer SCL1 adjacent to the first end portion EP1 and the second end portion EP2 of the light emitting element LD. The insulating film INF may secure electrical stability of the light emitting element LD. The insulating film INF can improve lifespan and efficiency by minimizing surface defects of the light emitting element LD. In case that light emitting elements LD are disposed close to each other, the insulating film INF can prevent short circuit defects between the light emitting elements LD.

According to an embodiment, the insulating film INF may include one or more selected from the group of silicon oxide (SiOₓ), silicon nitride (SiNₓ), silicon oxynitride (SiOₓN_{y}), aluminum oxide (AlₓO_{y}), and titanium oxide (TiOₓ). However, the disclosure is not limited to the examples described above.

The electrode layer ELL may be disposed on the second semiconductor layer SCL2. The electrode layer ELL may be adjacent to the second end portion EP2. The electrode layer ELL may be electrically connected to the second semiconductor layer SCL2. A portion of the electrode layer ELL may be exposed. For example, the insulating film INF may expose one surface or a surface of the electrode layer ELL. The electrode layer ELL may be exposed in an area corresponding to the second end portion EP2. According to the embodiment, a side surface of the electrode layer ELL may be exposed. For example, the insulating film INF may cover the side surface of each of the first semiconductor layer SCL1, the active layer AL, and the second semiconductor layer SCL2, but may not cover at least a portion of the side surface of the electrode layer ELL. Electrical connection between other constituent elements and the electrode layer ELL adjacent to the second end portion EP2 may be readily made. According to the embodiment, the insulating film INF may expose not only the side surface of the electrode layer ELL but also a portion of the side surface of the second semiconductor layer SCL2 and/or the first semiconductor layer SCL1.

According to an embodiment, the electrode layer ELL may be an ohmic contact electrode. However, the disclosure is not limited to the examples described above. For example, the electrode layer ELL may be a Schottky contact electrode.

According to an embodiment, the electrode layer ELL may include one or more selected from the group of chromium (Cr), titanium (Ti), aluminum (Al), gold (Au), nickel (Ni), oxides thereof, and alloys thereof. However, the disclosure is not limited to the examples described above. According to an embodiment, the electrode layer ELL may be substantially transparent. For example, the electrode layer ELL may include indium tin oxide (ITO). Accordingly, the electrode layer ELL can transmit the emitted light.

The structure and shape of the light emitting element LD are not limited to the examples described above, and the light emitting element LD may have various structures and shapes according to an embodiment. For example, the light emitting element LD may further include an additional electrode layer disposed on one surface or a surface of the first semiconductor layer SCL1 and adjacent to the first end portion EP1.

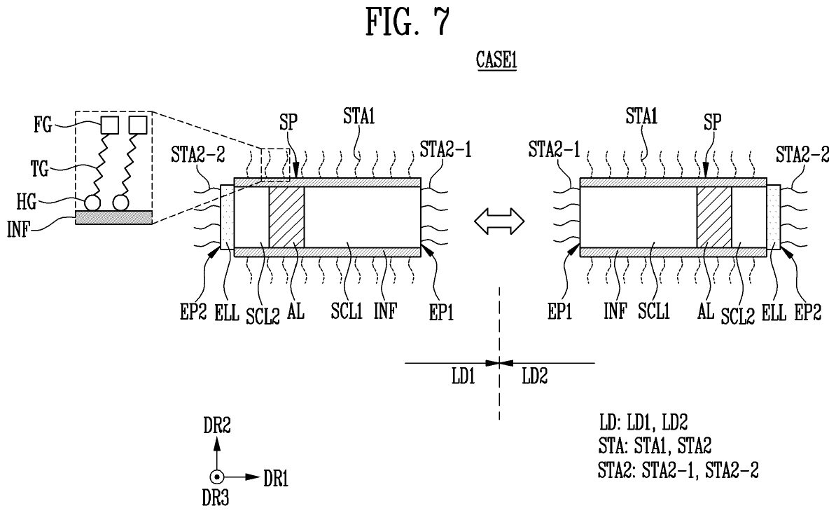

According to the embodiment, the light emitting element LD may further include a surface member STA (see FIG. 7) including a molecular structure formed on the outer surface of the light emitting element LD. According to the embodiment, the surface member STA may guide the light emitting elements LD to be appropriately aligned in case that the light emitting elements LD are disposed on the pixel-circuit layer PCL. Detailed information regarding this will be described later with reference to the drawings after FIG. 7.

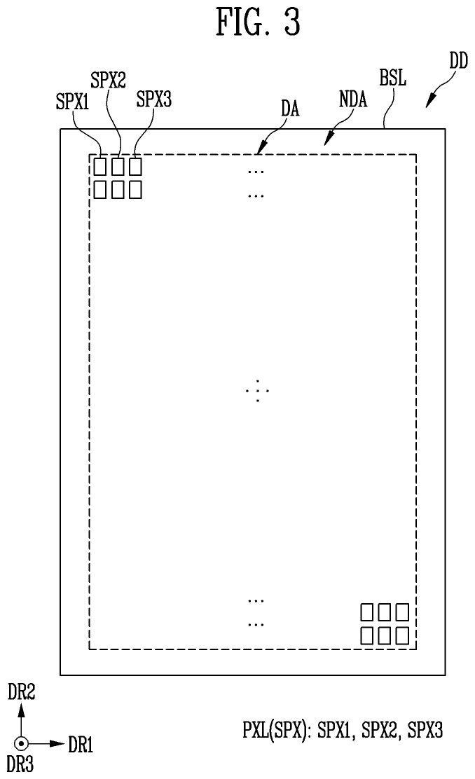

FIG. 3 is a schematic plan view illustrating a display device according to an embodiment.

Referring to FIG. 3, the display device DD may include a base layer BSL and a pixel PXL disposed on the base layer BSL and including light emitting elements LD. The display device DD may further include a driving circuit unit (for example, a scan driver and a data driver) for driving the pixel PXL, lines, and pads.

The display device DD (or base layer BSL) may include a display area DA and a non-display area NDA. The non-display area NDA may refer to an area other than the display area DA. The non-display area NDA may surround at least a portion of the display area DA.

The base layer BSL may form a base surface of the display device DD. The base layer BSL may be a rigid or flexible substrate or film. For example, the base layer BSL may be a rigid substrate made of glass or tempered glass, a flexible substrate (or thin film) made of plastic or metal, or an insulating layer of at least one layer or a layer. The material and/or physical properties of the base layer BSL are not particularly limited.

The display area DA may include an area in which the pixel PXL (for example, light emitting element LD) is disposed. The non-display area NDA may include an area (for example, dead space) in which the pixel PXL (for example, light emitting element LD) is not disposed. A driving circuit unit, wires, and pads connected to the pixel PXL of the display area DA may be disposed in the non-display area NDA.

According to the embodiment, the pixel PXL (or sub-pixel SPX) may be arranged (or disposed) according to a stripe or PENTILE™ array structure, etc., but is not limited thereto, and various embodiments are provided in the disclosure.

According to an embodiment, the pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be sub-pixels. At least one first sub-pixel SPX1, second sub-pixel SPX2, and third sub-pixel SPX3 may form one pixel unit to emit light of various colors.

For example, each of the first sub-pixel SPX), the second sub-pixel (SPX), and the third sub-pixel (SPX) may emit light of one color. For example, the first sub-pixel SPX1 may be a red pixel that emits red light (for example, first color), the second sub-pixel SPX2 may be a green pixel that emits green light (for example, second color), and the third sub-pixel SPX3 may be a blue pixel that emits blue light (for example, third color). According to an embodiment, the number of second sub-pixels SPX2 may be greater than the number of first and third sub-pixels SPX1 and SPX3. However, the color, type, and/or number of the first sub-pixel SPX1, the second sub-pixel SPX2, and the third sub-pixel SPX3 forming each pixel unit are not limited to specific examples.

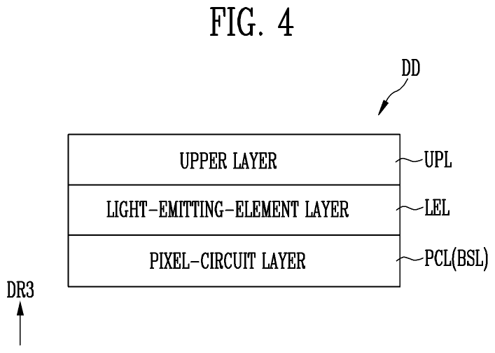

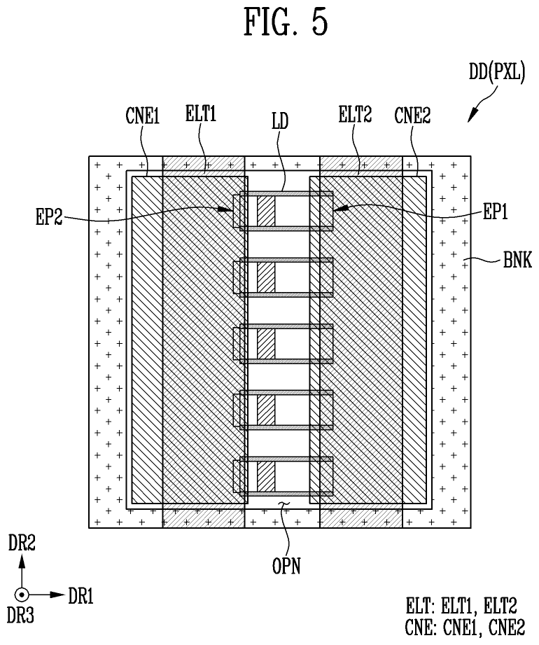

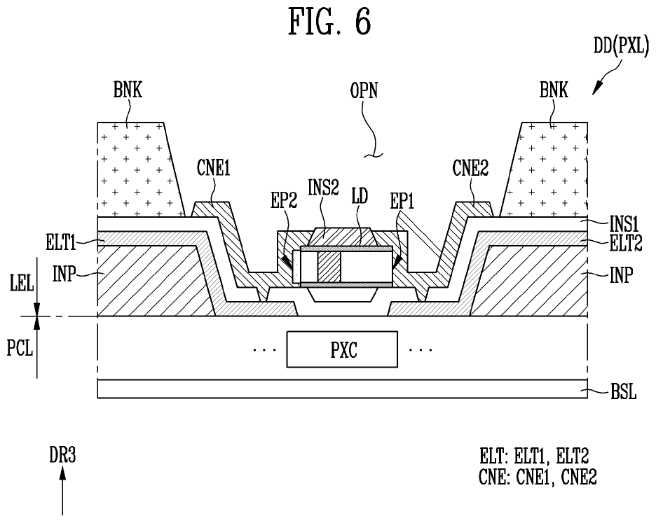

FIG. 4. is a schematic cross-sectional view illustrating a display device according to an embodiment. FIGS. 5 and 6 are schematic drawings for illustrating a pixel according to an embodiment. FIG. 5 may be a schematic plan view illustrating a pixel PXL (or display device DD) according to the embodiment. FIG. 6 may be a schematic cross-sectional view illustrating a pixel PXL (or display device DD) according to the embodiment.

Referring to FIGS. 4 to 6, the display device DD may include a pixel-circuit layer PCL (for example, backplane layer), a light-emitting-element layer LEL, and an upper layer UPL.

The pixel-circuit layer PCL may be a layer including a pixel circuit PXC for driving the pixel PXL formed by the light-emitting-element layer LEL (or the light emitting element LD included in the light-emitting-element layer LEL). The pixel-circuit layer PCL may include a base layer BSL, conductive layers for forming pixel circuits, and insulating layers disposed on the conductive layers.

The light-emitting-element layer LEL may be disposed on the pixel-circuit layer PCL. According to the embodiment, the light-emitting-element layer LEL may include a light emitting element LD. The light-emitting-element layer LEL may include a structure for aligning the light emitting elements LD.

The light-emitting-element layer LEL may include an insulating pattern INP, an alignment electrode ELT, a first insulating layer INS1, a bank BNK, a second insulating layer INS2, and a connection electrode CNE.

The insulating pattern INP may be disposed on the pixel-circuit layer PCL and may have a shape extending (or protruding) in the thickness direction (for example, third direction DR3) of the base layer BSL. At least a portion of each of the first and second electrodes ELT1 and ELT2 may be disposed on the insulating pattern INP to form a reflective wall.

The alignment electrode ELT may be a conductive structure for forming an electric field to align the light emitting element LD. The alignment electrode ELT may include a first electrode ELT1 and a second electrode ELT2 spaced apart from each other in the first direction DR1 (for example, spaced apart from each other in the direction in which the light emitting element LD extends). Each of the first electrode ELT1 and the second electrode ELT2 may extend in the second direction DR2.

In this specification, the first direction DR1 may refer to a direction in which the alignment electrodes ELT are spaced apart from each other. The second direction DR2 may refer to a direction in which the alignment electrodes ELT extend.

The first electrode ELT1 may be a first alignment electrode to which an alternating current signal can be supplied to align the light emitting elements LD. The first electrode ELT1 may be an electrode to which an anode signal can be supplied so that the light emitting elements LD emit light.

The second electrode ELT2 may be a second alignment electrode to which a ground signal can be supplied to align the light emitting elements LD. The second electrode ELT2 may be an electrode to which a cathode signal can be supplied so that the light emitting elements LD emit light.

According to the embodiment, the first electrode ELT1 may be electrically connected to the first connection electrode CNE1. The second electrode ELT2 may be electrically connected to the second connection electrode CNE2.

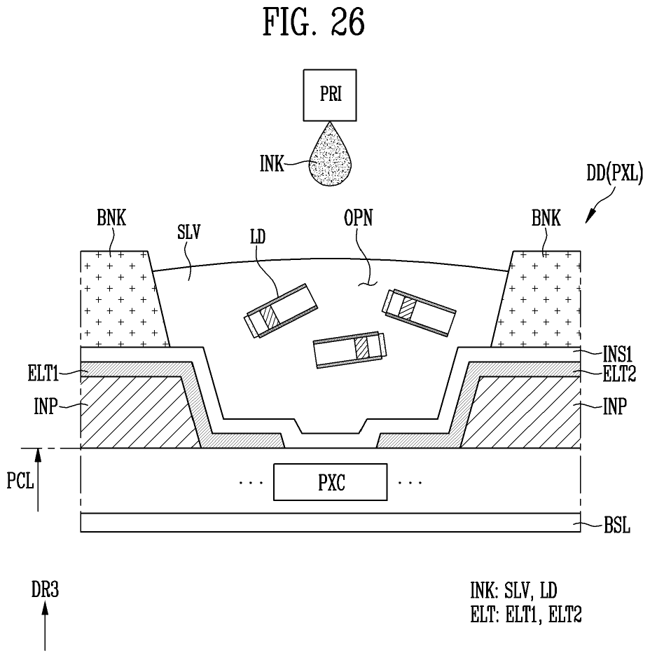

The first electrode ELT1 and the second electrode ELT2 may be supplied (or provided) with a first alignment signal and a second alignment signal, respectively, in a process in which the light emitting elements LD are aligned. For example, the ink INK (see FIG. 26) including the light emitting element LD may be supplied (or provided) to the opening OPN, the first alignment signal may be supplied to the first electrode ELT1, and the second alignment signal may be supplied to the second electrode ELT2.

The first alignment signal and the second alignment signal may have different waveforms, potentials, and/or phases. For example, the first alignment signal may be an alternating current signal and the second alignment signal may be a ground signal. However, the disclosure is not necessarily limited to the above-described embodiments.

An electric field may be formed between (or on) the first electrode ELT1 and the second electrode ELT2, and the light emitting elements LD may be aligned between the first electrode ELT1 and the second electrode ELT2 based on the electric field.

For example, the light emitting elements LD may be moved (or rotated) by a force (for example, dielectrophoresis (DEP) force) due to the electric field and may be aligned (or disposed) on the first electrode ELT1 and the second electrode ELT2.

The light emitting elements LD may be arranged (for example, sequentially arranged) in the second direction DR2. The light emitting elements LD may be spaced apart from each other in the second direction DR2. The light emitting elements LD may be arranged to extend in the first direction DR1 on the alignment electrode ELT. For example, the direction from the first end portion EP1 to the second end portion EP2 may be substantially parallel to the first direction DR1.

The first insulating layer INS1 may be disposed on the alignment electrode ELT. For example, the first insulating layer INS1 may cover the first electrode ELT1 and the second electrode ELT2. According to the embodiment, the first insulating layer INS1 may include an inorganic material.

The light emitting element LD may be disposed on the first insulating layer INS1. The light emitting element LD may be disposed between the first electrode ELT1 and the second electrode ELT2. The light emitting element LD may emit light based on an anode signal provided from the first connection electrode CNE1 and a cathode signal provided from the second connection electrode CNE2.

The second insulating layer INS2 may be disposed on the light emitting element LD. The second insulating layer INS2 may be an anchor. The second insulating layer INS2 can prevent the light emitting element LD from leaving an alignment position after being aligned. According to the embodiment, the second insulating layer INS2 may include an inorganic material or an organic material.

The bank BNK may be disposed on the first insulating layer INS1 (for example, insulating pattern INP). The bank BNK may protrude in the thickness direction (for example, third direction DR3) of the base layer BSL and may surround one area or an area. Accordingly, the bank BNK may form a space (for example, opening OPN) in which the ink INK can be accommodated. BNK may include organic materials.

The first connection electrode CNE1 and the second connection electrode CNE2 may be disposed on the first insulating layer INS1. The first connection electrode CNE1 may be electrically connected to the second end portion EP2 of the light emitting element LD. The second connection electrode CNE2 may be electrically connected to the first end portion EP1 of the light emitting element LD. According to the embodiment, the first connection electrode CNE1 and the second connection electrode CNE2 may include a conductive material (for example, transparent conductive material).

According to the embodiment, the first connection electrode CNE1 and the second connection electrode CNE2 may be patterned at a same time in a same process. However, the disclosure is not necessarily limited to the above-described embodiments. After one of the first connection electrode CNE1 and the second connection electrode CNE2 is patterned, the other thereof may be patterned.

The upper layer UPL may be disposed on the light-emitting-element layer LEL. According to the embodiment, the upper layer UPL may include a color conversion layer and a color filter layer. According to the embodiment, the upper layer UPL may further include a film layer.

According to the embodiment, the color filter layer may include a color filter material (for example, dye or pigment, etc.) that selectively transmits light of one color. For example, the color filter layer may include a first color filter included in the first sub-pixel SPX1, a second color filter included in the second sub-pixel SPX2, and a third color filter included in the third sub-pixel SPX3.

According to the embodiment, the color conversion layer may include quantum dots that can convert the color of light. According to the embodiment, the quantum dot may include a first quantum-dot that is included in the first sub-pixel SPX1 to convert light of the third color into light of the first color, and a second quantum-dot that is included in the second sub-pixel SPX2 to convert light of the third color into light of the second color.

According to the embodiment, the film layer may include at least one selected from the group consisting of a polyethyleneterephthalate (PET) film, a low-reflection film, a polarizing film, and a transmittance controllable film. However, the disclosure is not limited thereto.

The structure of the upper layer UPL is not limited to the above-described examples and may include various structures.

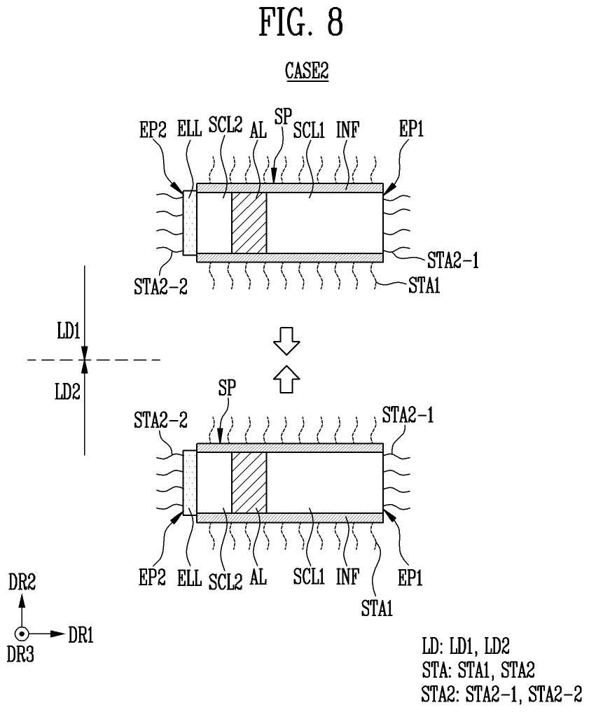

With reference to FIGS. 7 and 8, a surface member STA of the light emitting element LD will be described. For convenience of description, duplicate description is briefly explained or not repeated.

FIGS. 7 and 8 are schematic drawings illustrating a light emitting element including a surface member according to an embodiment. FIGS. 7 and 8 may illustrate a light emitting element LD including a surface member STA, and schematically illustrate an arrangement relationship between the light emitting elements LD.

First, the surface member STA of the light emitting element LD will be described, and the arrangement relationship between the light emitting elements LD will be described.

The light emitting element LD may include a surface member STA. The surface member STA may be formed on an outer surface of the light emitting element LD. The surface member STA may be disposed on the side portion SP of the light emitting element LD. The surface member STA may be disposed on the end portions EP1 and EP2 of the light emitting element LD. The surface member STA may be a structure formed on an outermost portion of the light emitting element LD.

The surface member STA may include molecular assemblies formed on the outer surface of the light emitting element LD. The surface member STA may include a molecular layer attached to the object. According to the embodiment, the surface member STA may form a single layer of molecular assembly layer.

For example, the molecular assemblies included in the surface member STA may include a head group HG, a functional group FG, and a tail group TG connecting the head group HG and the functional group FG. The molecular assemblies may form a surface treatment structure including a surface member STA on the outer surface of the light emitting element LD.

The head group HG may be attached to an object to which the surface member STA is attached (for example, the outer surface of the light emitting element LD). The head group HG may be adsorbed on the outer surface of the light emitting element LD, allowing the surface member STA to stably form a molecular layer structure on the outer surface of the light emitting element LD. The functional group FG may be connected to the head group HG through the tail group TG and may face the outside of the light emitting element LD.

According to the embodiment, the surface member STA may be obtained by performing a surface treatment process on the light emitting element LD. The way the surface treatment process is performed can be performed using a variety of processes. For example, the surface treatment process may be performed by immersing the object in a solution including a surface treatment agent. However, the disclosure is not particularly limited.

According to the embodiment, the surface member STA may include at least one material selected from the group consisting of a silane material, a phosphonate material, a carboxylate material, a catechol material, an alkyne material, alkene material, and amine material, and may include a functional group FG having one surface energy.

The surface member STA may include a first surface member STA1 and a second surface member STA2.

The first surface member STA1 may be formed on the side portion SP of the light emitting element LD. The first surface member STA1 may be formed on the insulating layer INF.

The second surface member STA2 may be formed on the end portions EP1 and EP2 of the light emitting element LD. The second surface member STA2 may include a (2-1) surface member STA2-1 and a (2-2) surface member STA2-2.

The (2-1)st surface member STA2-1 may be formed at the first end portion EP1. The (2-1) surface member STA2-1 may be formed on one surface or a surface of the first semiconductor layer SCL1. The (2-2) surface member STA2-2 may be formed at the second end portion EP2. The (2-2) surface member STA2-2 may be formed on one surface or a surface of the electrode layer ELL.

The first surface member STA1 and the second surface member STA2 may include different materials.

According to the embodiment, the first surface member STA1 and the second surface member STA2 may include different functional groups FG to have different surface energies.

For example, the head group HG and tail group TG of each of the first surface member STA1 and the second surface member STA2 may be a same or different from each other. The functional groups FG of each of the first surface member STA1 and the second surface member STA2 may be different from each other.

For example, the first surface member STA1 may include a first functional group and have a first surface energy. The second surface member STA2 may include a second functional group different from the first functional group and may have a second surface energy smaller than the first surface energy.

According to the embodiment, the first functional group may include more polar components than the second functional group. Accordingly, the first surface member STA1 including the first functional group may have a higher surface energy than the second surface member STA2 including the second functional group.

For example, the first functional group may include one of a hydroxyl group (—OH) and a carboxyl group (—COOH). The second functional group may include one of a methyl group (—CH3) and a fluorine group (—F). However, the disclosure is not limited thereto.

According to the embodiment, the molecular assemblies of each of the (2-1) surface member STA2-1 and the (2-2) surface member STA2-2 may be identical to each other. For example, the second functional groups of each of the (2-1) surface member STA2-1 and the (2-2) surface member STA2-2 may be identical to each other.

By way of example, according to embodiments, the molecular assemblies of each of the (2-1) surface member STA2-1 and the (2-2) surface member STA2-2 may be different from each other. For example, the second functional groups of each of the (2-1) surface member STA2-1 and the (2-2) surface member STA2-2 may be different from each other.

According to the embodiment, the concentration (for example, number per unit area) of the molecular assembly for forming the second surface member STA2 on the end portions EP1 and EP2 may be greater than the concentration of the molecular assembly for forming the first surface member STA1 on the side portion SP. However, the disclosure is not limited thereto.

For example, the concentration (for example, number per unit area) of the molecular assembly for forming the second surface member STA2 on the end portions EP1 and EP2 may be substantially a same as the concentration of the molecular assembly for forming the first surface member STA1 on the side portion SP.

According to the light emitting element LD according to the embodiment, the surface energy defined at the side portion SP may be greater than the surface energy defined on the end portions EP1 and EP2. Experimentally, two objects with a low surface energy may have a large repulsive force against each other, and two objects with a large surface energy may have a relatively small repulsive force against each other.

Accordingly, the light emitting elements LD different from each other may have a greater tendency for their side portions SP to be adjacent to each other than the tendency for their end portions EP1 and EP2 to be adjacent to each other.

As described above, the light emitting elements LD may be arranged so that the direction from the first end portion EP1 to the second end portion EP2 corresponds to the direction in which the alignment electrodes ELT are spaced apart from each other and may be supplied electrical signals for emitting light. For example, the direction from the (2-1) surface member STA2-1 to the (2-2) surface member STA2-2 may be a same the direction in which the first electrode ELT1 and the second electrode ELT2 are spaced apart from each other.

FIG. 7 illustrates the arrangement relationship between the first light emitting element LD1 and the second light emitting element LD2 in case that the first light emitting element LD1 and the second light emitting elements LD2 are adjacent to each other in the direction in which the end portions EP1 and EP2 of each of the first light emitting element LD1 and the second light emitting element LD2 included in the light emitting elements LD are spaced apart from each other. FIG. 7 may illustrate a first case (CASE1) in which the light emitting elements LD are adjacent to each other in the first direction DR1 on adjacent alignment electrodes ELT. The first case (CASE1) may represent an arrangement in which the light emitting elements LD are not appropriately aligned.

FIG. 8 illustrates the arrangement relationship between the first light emitting element LD1 and the second light emitting element LD2 in case that the first light emitting element LD1 and the second light emitting elements LD2 are adjacent to each other in the direction different from the direction in which the end portions EP1 and EP2 of each of the first light emitting element LD1 and the second light emitting element LD2 included in the light emitting elements LD are spaced apart from each other. FIG. 8 may illustrate a second case (CASE2) in which light emitting elements LD are adjacent to each other in the second direction DR2 on adjacent alignment electrodes ELT. The second case (CASE2) may represent an arrangement in which the light emitting elements LD are appropriately aligned.

According to the embodiment, in case that the light emitting elements LD are adjacent to each other in the first direction DR1, and the direction from the first end portion EP1 of each of the light emitting elements LD to the second end portion EP2 is substantially a same as the first direction DR1 (for example, is different from the second direction DR2), it may be difficult to for the first end portion EP1 and the second end portion EP2 of each of the light emitting elements LD properly electrically connect the connection electrode CNE2 and the first connection electrode CNE1, and it may be difficult for the light emitting elements LD to be properly aligned.

Experimentally, a form in which the end portions EP1 and EP2 of the light emitting elements LD are sequentially arranged adjacent to each other may be referred to as a non-luminous agglomeration form, and the risk of forming the non-luminous agglomeration form needs to be reduced.

In case that the light emitting elements LD are adjacent to each other in the second direction DR2, and the direction from the first end portion EP1 of each light emitting element LD to the second end portion EP2 is substantially different from the first direction DR1 (for example, is a same as the second direction DR2), the first end portion EP1 and the second end portion EP2 of each of the light emitting elements LD may be appropriately electrically connected to the second connection electrode CNE2 and the first connection electrode CNE1, and it may be interpreted that the light emitting elements LD are normally aligned.

As a result, it may be relatively appropriate for the light emitting elements LD to have a greater tendency to be arranged in the structure of the second case (CASE2) than to have a tendency to be arranged in the structure of the first case (CASE1). According to the embodiment, the light emitting elements LD may have a greater tendency to be arranged in the structure of the second case (CASE2) than the tendency to be arranged in the structure of the first case (CASE1).

For example, as shown in FIG. 7 in case that the end portions EP1 and EP2 of each of the first and second light emitting elements LD1 and LD2 are adjacent to each other, the second surface member STA2 has a relatively low surface energy, so the first light emitting element LD1 and the second light emitting element LD2 may be spaced apart from each other by a strong repulsive force.

On the contrary, as shown in FIG. 8, in case that the side portions SP of each of the first light emitting element LD1 and the second light emitting element LD2 are adjacent to each other, the first surface member STA1 has a relatively high surface energy, so the first light emitting element LD1 and the second light emitting element LD2 may be spaced apart from each other by a relatively weak repulsive force.

Accordingly, the first light emitting element LD1 and the second light emitting element LD2 may have a greater tendency to be arranged so that side portions SP thereof are adjacent to each other. Referring to FIG. 5, the first light emitting element LD1 and the second light emitting element LD2 may need to be arranged so that side portions SP thereof face each other.

As the (2-1) surface member STA2-1 and the (2-2) surface member STA2-2 having relatively low surface energy are formed at both end portions EP1 and EP2 of the light emitting element LD, the light emitting elements LD may have an array structure suitable for being aligned on the alignment electrodes ELT.

In case that the light emitting elements LD are not appropriately aligned, the number of light emitting elements LD supplied on the alignment electrodes ELT may increase in order to implement the pixel PXL with the intended luminance, thereby increasing the process cost. However, according to the embodiment, this risk can be reduced, and the effect of reducing process costs can also be provided.

Accordingly, the risk of the light emitting elements LD being abnormally aligned is reduced, so the alignment of the light emitting elements LD can be significantly improved, and the light emitting elements LD operate normally, thereby improving the luminous efficiency.

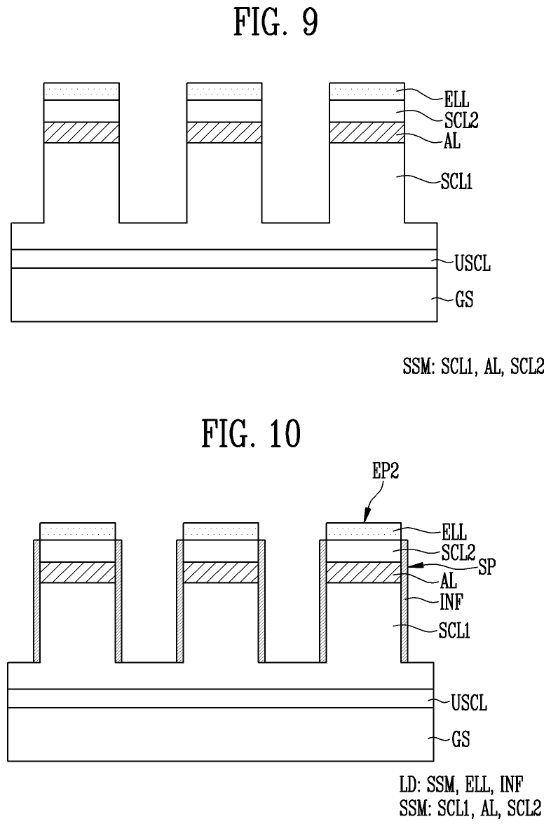

With reference to FIGS. 9 to 20, a manufacturing method of a light emitting element LD according to the embodiment will be described. For convenience of description, duplicate description is briefly explained or not repeated.

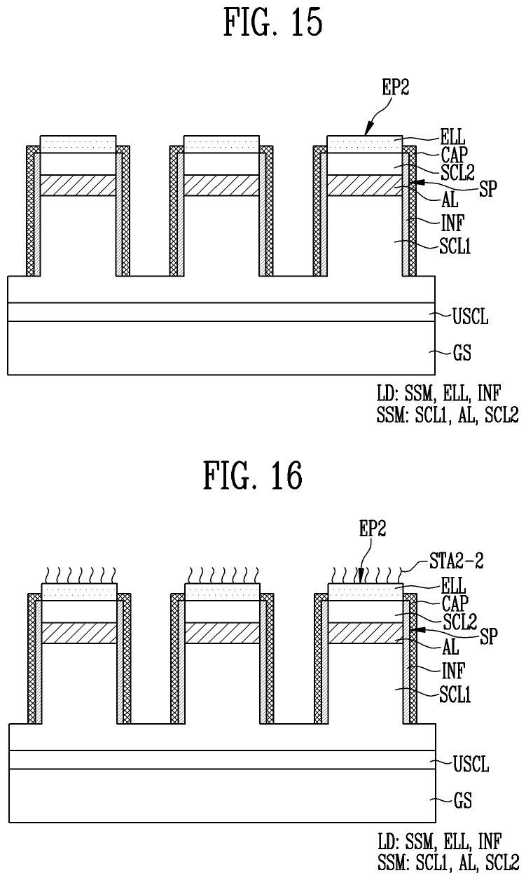

FIGS. 9 to 20 are schematic drawings illustrating each process step of a manufacturing method of a light emitting element according to an embodiment. FIGS. 9 to 14 illustrate a manufacturing method of the light emitting element LD in which the (2-1) surface member STA2-1 and the (2-2) surface member STA2-2 have a same structure. FIGS. 15 to 20 illustrate a manufacturing method of the light emitting element LD in which the (2-1) surface member STA2-1 and the (2-2) surface member STA2-2 have different structures.

First, with reference to FIGS. 9 to 14, the manufacturing method of the light emitting element LD in which the (2-1) surface member STA2-1 and the (2-2) surface member STA2-2 have a same structure will be described.

Referring to FIG. 9, an undoped semiconductor layer USCL, a first base semiconductor layer for forming the first semiconductor layer SCL1, a base active layer for forming the active layer AL, and a second base semiconductor layer for forming the second semiconductor layer SCL2 may be formed (for example, be epitaxially grown) on a growth substrate GS, and at least a portion of each of the first base semiconductor layer, the base active layer, and the second base semiconductor layer may be etched (for example, be dry etched) so that the semiconductor stacked member SSM including the first semiconductor layer SCL1, the active layer AL, and the second semiconductor layer SCL2 may be patterned.

The growth substrate GS may be a base plate for growing a target material. For example, the growth substrate GS may be a wafer for epitaxial growth of a material. The growth substrate GS may be a substrate including Si, GaAs, etc., but materials for forming the growth substrate GS are not limited to specific examples.

The undoped semiconductor layer USCL can reduce defects in semiconductor layers formed on the growth substrate GS. According to the embodiment, the undoped semiconductor layer USCL may be a semiconductor material that does not include a separate dopant and may include a same material as the semiconductor material for forming the semiconductor stacked member SSM, but the material for forming the undoped semiconductor layer USCL is not limited to specific examples.

Referring to FIG. 10, the electrode layer ELL may be patterned on the semiconductor stacked member SSM, and the insulating layer INF may be patterned to cover one side surface or a side surface of the semiconductor stacked member SSM.

The electrode layer ELL may be patterned on an upper surface of each semiconductor stacked member SSM. For example, the electrode layer ELL may be manufactured by being deposited using various methods and etched. Accordingly, the electrode layer ELL may expose the side surface of each of the semiconductor stack members SSM and may be electrically connected to the second semiconductor layer SCL2.

The insulating layer INF may be formed (or deposited) by various methods and may be manufactured by etching. For example, an atomic layer deposition (ALD) process or a chemical vapor deposition (CVD) process may be used. However, the disclosure is not necessarily limited thereto. The formed insulating layer INF may be etched to electrically expose the semiconductor stacked member SSM.

By performing this step, a light emitting element LD including the semiconductor stacked member SSM, the electrode layer ELL, and the insulating layer INF may be prepared.

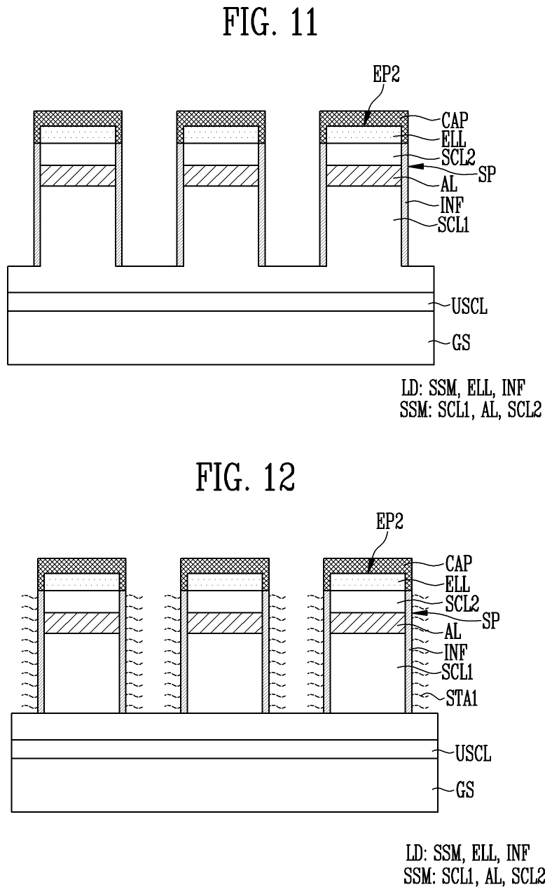

Referring to FIG. 11, the capping layer CAP may be patterned.

The capping layer CAP may be patterned to overlap the semiconductor stacked member SSM and the insulating layer INF in a plan view. The capping layer CAP may entirely cover the electrode layer ELL. The capping layer CAP may expose the side portion SP of the light emitting element LD. The capping layer CAP may expose the insulating layer INF.

The capping layer CAP may include a photoresist material. For example, the capping layer CAP may have an organic material that is photosensitive. However, the disclosure is not limited to specific examples. A photosensitive material may be used to form the capping layer CAP, and the capping layer CAP may be appropriately removed in a later process.

Referring to FIG. 12, a surface treatment process on the light emitting element LD may be performed while the capping layer CAP is disposed to expose the insulating layer INF.

The surface treatment process may be a process for forming a surface member STA including a molecular assembly layer on the surface of the light emitting element LD. For example, as described above, the surface treatment process may be performed by immersing in a solution including a surface treatment agent. However, various methods may be applied to the surface treatment process.

In this step, the first surface member STA1 may be formed on the insulating layer INF. Since the surface treatment process may be performed while the capping layer CAP covers the electrode layer ELL, the first surface member STA1 may be selectively formed on the side portion SP of the light emitting element LD.

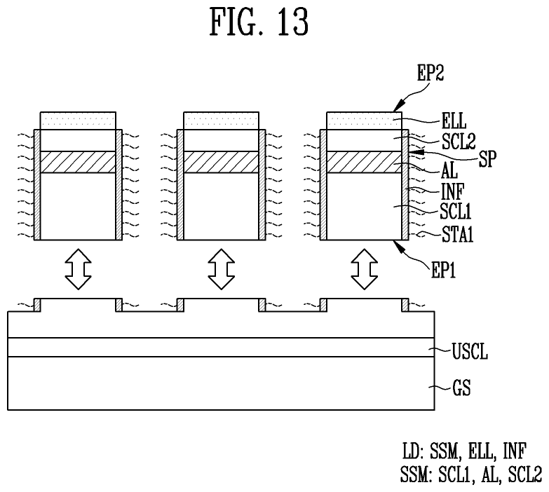

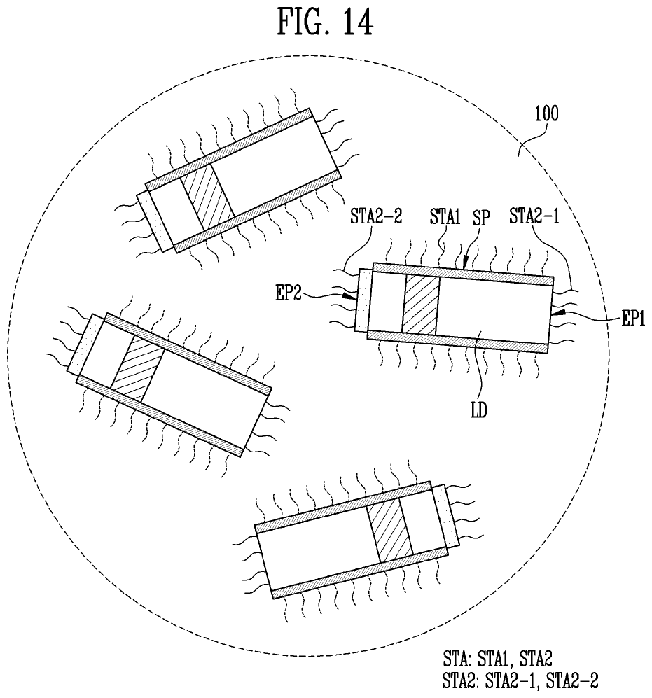

Referring to FIG. 13, the capping layer CAP may be removed, the light emitting element LD may be separated from the growth substrate GS, and individual light emitting elements LD may be prepared.

In this step, the capping layer CAP may be removed by various methods. For example, as the capping layer CAP may include a photosensitive material, a strip process or the like may be performed to remove the capping layer CAP. However, the disclosure is not limited thereto.

In this step, at least a portion of the first semiconductor layer SCL1 may be cut. According to the embodiment, a laser lift off (LLO) process may be performed to cut a portion of the first semiconductor layer SCL1. However, the disclosure is not necessarily limited thereto.

Referring to FIG. 14, after the light emitting element LD is separated from the growth substrate GS, a surface treatment process may be performed on the light emitting element LD.

The surface treatment process performed in this step may be referred to as an additional surface treatment process.

According to the embodiment, the light emitting element LD may be immersed in a surface treatment solution 100 including a surface treatment agent forming the second surface member STA2, and accordingly the second surface member STA2 may be formed on the end portions EP1 and EP2 of the light emitting element LD.

According to the embodiment, since the surface treatment process is performed with the first surface member STA1 formed on the side portion SP of the light emitting element LD, the second surface member STA2 may be formed on the end portions EP1 and EP2 of the light emitting element LD.

Accordingly, the light emitting element LD may be manufactured in which the first surface member STA1 is disposed on the side portion SP and the second surface member STA2 is disposed on the end portions EP1 and EP2.

In reference to FIGS. 15 to 20, the manufacturing method of the light emitting element LD including the (2-1) surface member STA2-1 and the (2-2) surface member STA2-2 have different structures. For convenience of description, duplicate description is briefly explained or not repeated with reference to FIGS. 9 to 14.

Referring to FIG. 15, a capping layer CAP may be patterned on the side portion SP of each of the light emitting elements LD patterned on the growth substrate GS.

In this step, the capping layer CAP may expose the electrode layer ELL and may completely cover the insulating layer INF.

Referring to FIG. 16, a surface treatment process on the light emitting element LD may be performed while the capping layer CAP is disposed to expose the electrode layer ELL.

In this step, the second surface member STA2 may be formed on the electrode layer ELL. Since the surface treatment process may be performed while the capping layer CAP covers the insulating layer INF, the second surface member STA2 may be selectively formed on the end portions EP1 and EP2 of the light emitting element LD.

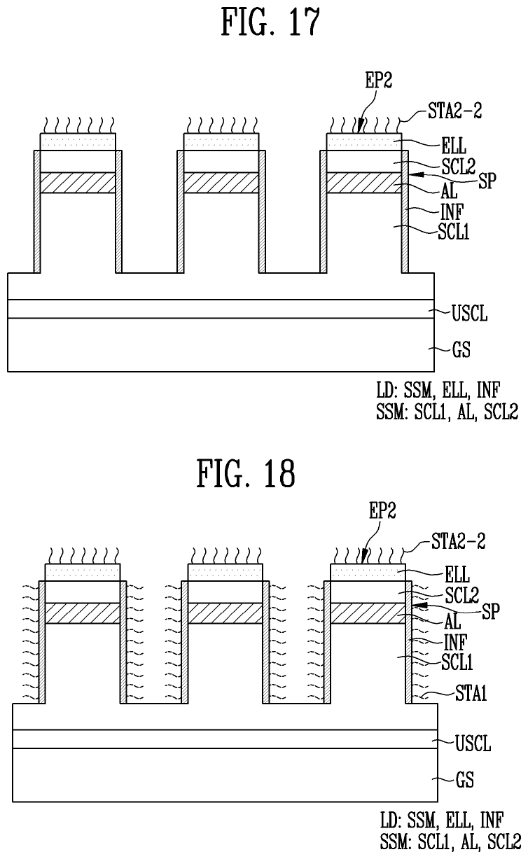

Referring to FIG. 17, the capping layer CAP may be removed. Accordingly, while the (2-2) surface member STA2-2 is formed on the electrode layer ELL, the side portion SP of the light emitting elements LD may be exposed.

Referring to FIG. 18, while the (2-2) surface member STA2-2 is formed on the electrode layer ELL, a surface treatment process on the light emitting element LD may be performed.

In this step, the first surface member STA1 may be formed on the insulating layer INF. Since the surface treatment process may be performed with the (2-2) surface member STA2-2 formed on the electrode layer ELL, the first surface member STA1 may be selectively formed on the side portion SP of the light emitting element LD.

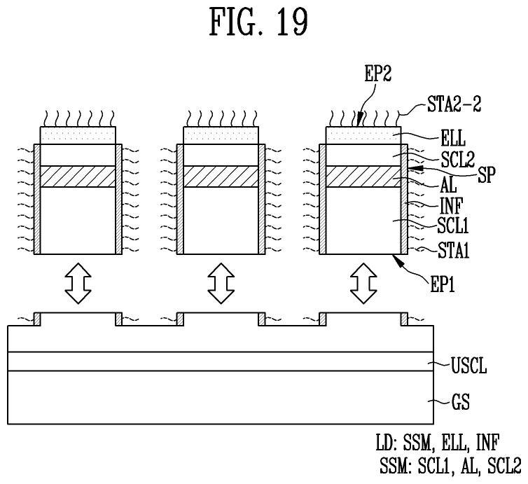

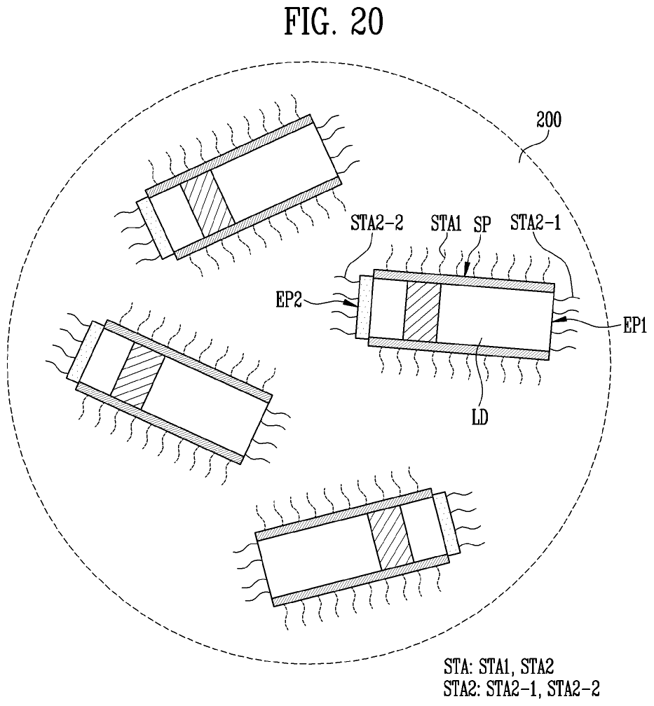

Referring to FIG. 19, the light emitting element LD may be separated from the growth substrate GS, and individual light emitting elements LD may be prepared.

According to the embodiment, while the first surface member STA1 is formed on the side portion SP and the second surface member STA2-2 is formed on the electrode layer ELL, the light emitting element LD is separated.

Referring to FIG. 20, after the light emitting element LD is separated from the growth substrate GS, a surface treatment process may be performed on the light emitting element LD.

The surface treatment process performed in this step may be referred to as an additional surface treatment process.

According to the embodiment, the light emitting element LD may be immersed in a solution 200 for additional surface treatment including a surface treatment agent forming the (2-1) surface member STA2-1, and accordingly the (2-1) surface member STA2-1 may be formed at the first end portion EP1 of the light emitting element LD. Accordingly, the (2-1) surface member STA2-1 and the (2-2) surface member STA2-2 may be prepared to include different materials.

According to the embodiment, while the first surface member STA1 is formed on the side portion SP of the light emitting element LD, and the (2-2) surface member STA2-2 is formed on the second end portion EP2, the surface treatment process is performed, so the (2-1) surface member STA2-1 may be formed at the first end portion EP1 of the light emitting element LD.

Accordingly, the light emitting element LD may be manufactured in which the first surface member STA1 is disposed on the side portion SP and the (2-1) surface members STA2-1 and the (2-2) surface members STA2-2 different from each other are disposed on the end portions EP1 and EP2.

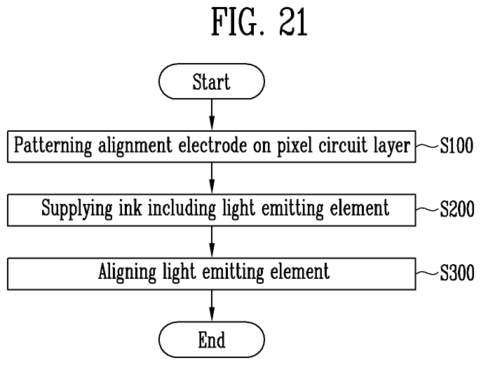

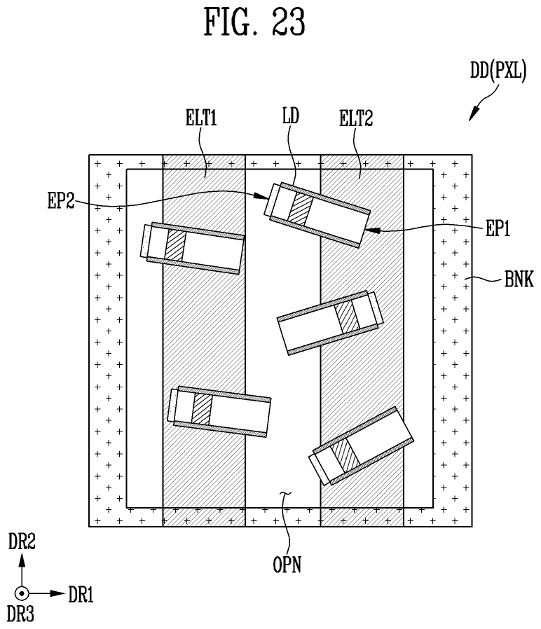

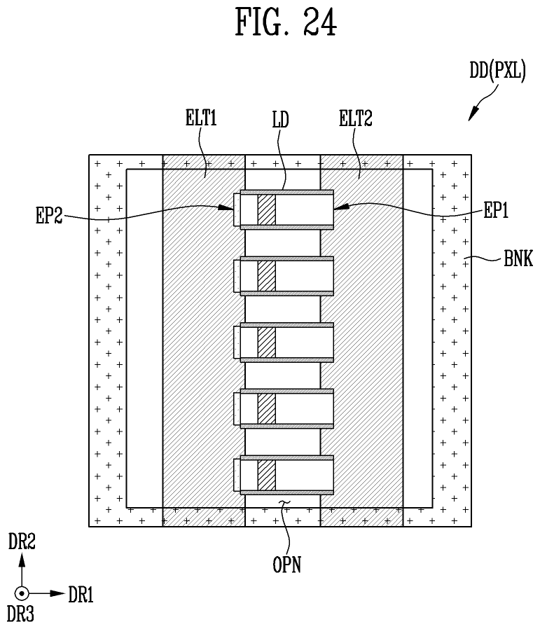

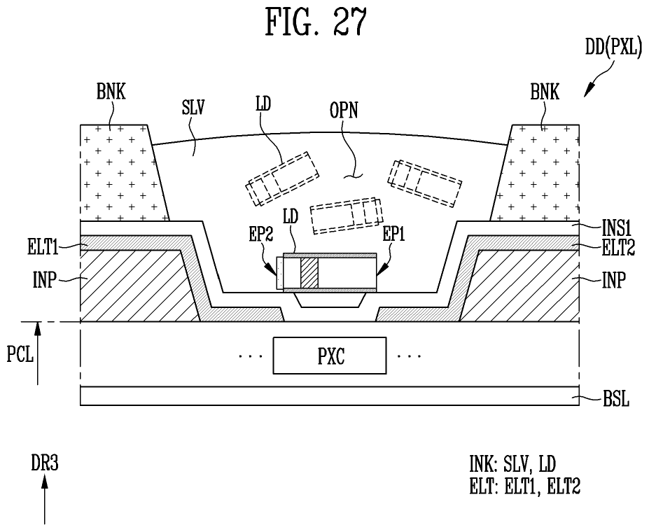

With reference to FIGS. 21 to 27, a manufacturing method of a display device DD including the light emitting element LD according to the embodiment will be described. For convenience of description, duplicate description is briefly explained or not repeated.

FIG. 21 is a flowchart illustrating a manufacturing method of a display device according to an embodiment.

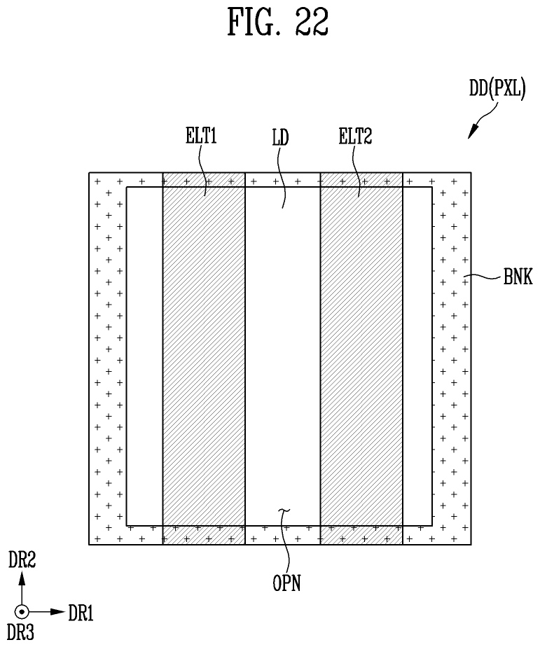

FIGS. 22 to 24 are schematic plan views illustrating each process step of a manufacturing method of a display device according to an embodiment. For convenience of description, FIGS. 22 to 24 illustrate planar structures for each process step based on the cross-sectional structure shown in FIG. 5.

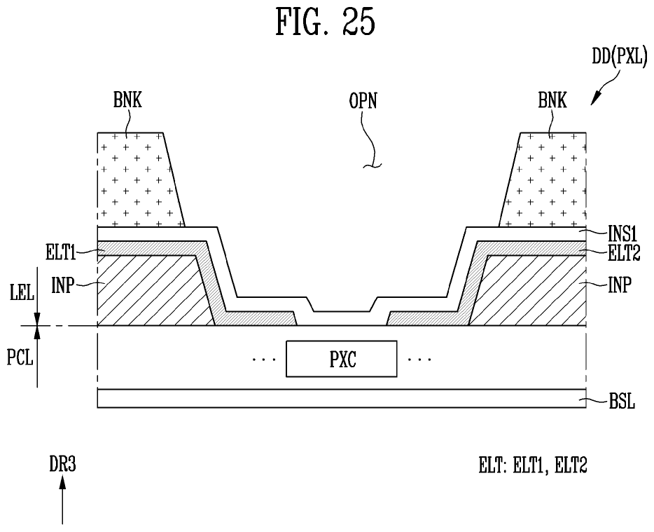

FIGS. 25 to 27 are schematic cross-sectional views illustrating each process step of a manufacturing method of a display device according to an embodiment. For convenience of description, FIGS. 25 to 27 illustrate the cross-sectional structure for each process step based on the cross-sectional structure shown in FIG. 6.

The manufacturing method of the display device DD according to the embodiment may include manufacturing the display device DD using the light emitting element LD manufactured according to the manufacturing method of the light emitting element LD described above.

For example, referring to FIG. 21, the manufacturing method of the display device DD according to the embodiment may include patterning an alignment electrode on a pixel-circuit layer (S100), supplying ink including a light emitting element (S100), S200), and aligning the light emitting elements (S300).

Referring to FIGS. 21, 22, and 25, in the patterning the alignment electrode on the pixel-circuit layer (S100), a base layer BSL is prepared, conductive layers and insulating layers are disposed on the base layer BSL to form a pixel circuit PXC, and a pixel-circuit layer PCL is provided, and alignment electrodes ELT may be patterned on the pixel-circuit layer PCL (for example, base layer BSL).

A conductive layer or an insulating layer on the base layer (BSL) may be formed based on a selected process for manufacturing a semiconductor device. For example, the conductive layer or the insulating layer on the base layer (BSL) may be formed by a photolithography process and may be deposited by various methods (for example, sputtering, chemical vapor deposition, etc.). The disclosure is not necessarily limited to examples.

In this step, before the alignment electrode ELT is deposited, the insulating pattern INP may be patterned on the pixel-circuit layer PCL. After the alignment electrode ELT is patterned, the first insulating layer INS1 may be formed on the first electrode ELT1 and the second electrode ELT2. After the first insulating layer INS1 is formed, the bank BNK may be patterned (for example, formed) to form the opening OPN.

Referring to FIGS. 21, 23, and 26, in the supplying the ink including the light emitting element (S200), an inkjet printer PRI may provide (for example, eject) an ink INK including a light emitting element LD and a solvent SLV on the base layer BSL.

In this step, the ink INK ejected by the inkjet printer PRI may be supplied into the opening OPN defined by the bank BNK. The light emitting elements LD may be disposed dispersedly in the solvent SLV before being aligned.

According to an embodiment, the solvent (SLV) may include an organic solvent. For example, the solvent (SLV) may be at least one selected from propylene glycol methyl ether acetate (PGMEA), dipropylene glycol n-propyl ether (DGPE), and triethylene glycol n-butyl ether (TGBE). However, the disclosure is not limited to the examples described above.

According to the embodiment, an inkjet printer PRI may eject fluid. For example, the inkjet printer PRI may include a nozzle unit through which the ink INK is ejected, an ink channel fluidly connected to the nozzle unit, and an ink reservoir fluidly connected to the ink channel, and the inkjet printer PRI may be moved in a plane direction on the pixel-circuit layer PCL. Accordingly, the inkjet printer PRI may eject the ink INK to each of some or a number of areas of the pixel-circuit layer PCL.

Referring to FIGS. 21, 24, and 27, in the aligning the light emitting element (S300), an alignment signal may be supplied to the first electrode ELT1 and the second electrode ELT2, and the light emitting elements LD may be aligned based on an electric field formed according thereto.

As discussed above, the light emitting elements LD may have a tendency to be arranged so that the side portions SP are adjacent to each other and may a tendency to be arranged so that the end portions EP1 and EP2 are not adjacent to each other. Accordingly, the light emitting elements LD can be aligned with excellent alignment.

Thereafter, according to the embodiment, the solvent SLV may be removed and the connection electrode CNE electrically connected to the light emitting element LD may be patterned, thereby manufacturing the light-emitting-element layer LEL. Thereafter, the upper layer UPL may be disposed on the light-emitting-element layer LEL, thereby manufacturing the display device DD according to the embodiment.

As described above, while the disclosure has been shown and described with reference to embodiments thereof, it will be understood by those skilled in the art that various changes in forms and details may be made therein without departing from the spirit and scope of the disclosure and as defined by the appended claims and their equivalents.

Accordingly, the technical scope of the disclosure may be determined by the technical scope of the accompanying claims.

What is claimed is:

1. A light emitting element comprising:
end portions including a first end portion and a second end portion;
a side portion disposed between the first end portion and the second end portion;
a semiconductor stacked member including a first semiconductor layer adjacent to the first end portion, a second semiconductor layer adjacent to the second end portion, and an active layer disposed between the first semiconductor layer and the second semiconductor layer;
a first surface member disposed on the side portion, the first surface member having a first surface energy; and
a second surface member disposed on the end portions, the second surface member having a second surface energy less than the first surface energy of the first surface member.

2. The light emitting element of claim 1, wherein
each of the first surface member and the second surface member includes at least one material selected from the group consisting of a silane material, a phosphonate material, a carboxylate material, a catechol material, an alkyne material, an alkene material, and an amine material,
the first surface member includes a first functional group, and
the second surface member includes a second functional group different from the first functional group.

3. The light emitting element of claim 2, wherein the first functional group includes one of a hydroxyl group (—OH) and a carboxyl group (—COOH).

4. The light emitting element of claim 2, wherein the second functional group includes one of a methyl group (—CH3) and a fluorine group (—F).

5. The light emitting element of claim 1, further comprising:
an insulating layer disposed on the semiconductor stacked member,
wherein the first surface member is disposed on the insulating layer.

6. The light emitting element of claim 5, further comprising:
an electrode layer adjacent to the second end portion and disposed on the second semiconductor layer, wherein
the second surface member includes a (2-1) surface member disposed on the first end portion and a (2-2) surface member disposed on the second end portion,
the (2-1) surface member is disposed on the first semiconductor layer, and
the (2-2) surface member is disposed on the electrode layer.

7. The light emitting element of claim 6, wherein the (2-1) surface member and the (2-2) surface member include a same material.

8. The light emitting element of claim 6, wherein the (2-1) surface member and the (2-2) surface member include different materials.

9. The light emitting element of claim 1, wherein
each of the first surface member and the second surface member includes molecular assemblies, and
the molecular assemblies form a surface treatment structure on an outer surface of the light emitting element.

10. The light emitting element of claim 9, wherein a number of the molecular assemblies forming the second surface member per unit area on which the second surface member is disposed is greater than a number of the molecular assemblies forming the first surface member per unit area on which the first surface member is disposed.

11. A manufacturing method of a light emitting element comprising:
patterning a semiconductor stacked member including a first semiconductor layer, a second semiconductor layer, and an active layer disposed between the first semiconductor layer and the second semiconductor layer on a growth substrate;
separating a light emitting element including the semiconductor stacking member from the growth substrate;
performing a surface treatment on the light emitting element before the separating of the light emitting element including the semiconductor stacked member from the growth substrate; and
performing an additional surface treatment on the light emitting element after the separating of the light emitting element including the semiconductor stacked member from the growth substrate.

12. The manufacturing method of claim 11, further comprising:
patterning an electrode layer on an upper surface of the semiconductor stacked member; and
patterning an insulating layer on a side surface of the semiconductor stacked member.

13. The manufacturing method of claim 12, further comprising:
patterning a capping layer exposing the insulating layer,
wherein the patterning the capping layer is performed before the performing the surface treatment.

14. The manufacturing method of claim 13, wherein
the performing of the surface treatment includes forming a first surface member on the insulating layer,
the performing of the additional surface treatment includes forming a second surface member at both end portions of the light emitting element, and
the second surface member has a lower surface energy than a surface energy of the first surface member.

15. The manufacturing method of claim 12, further comprising:
patterning a capping layer exposing the electrode layer,
wherein the patterning of the capping layer is performed before the performing the surface treatment.

16. The manufacturing method of claim 15, wherein
the performing of the additional surface treatment includes forming a (2-1) surface member on the first semiconductor layer, and
the performing of the surface treatment includes forming a (2-2) surface member on the electrode layer.

17. A display device comprising:
a first electrode and a second electrode on a base layer; and
light emitting elements aligned between the first electrode and the second electrode, wherein
each of the light emitting elements includes:
end portions including a first end portion and a second end portion;
a side portion disposed between the first end portion and the second end portion;
a semiconductor stacked member including a first semiconductor layer adjacent to the first end portion, a second semiconductor layer adjacent to the second end portion, and an active layer disposed between the first semiconductor layer and the second semiconductor layer;
a first surface member disposed on the side portion of each of the light emitting elements, the first surface member having a first surface energy, and
a second surface member disposed on the end portions of each of the light emitting elements, the second surface member having a second surface energy less than the first surface energy of the first surface member.

18. The display device of claim 17, wherein
the second surface member includes a (2-1) surface member adjacent to the first end portion and a (2-2) surface member adjacent to the second end portion, and
a direction from the (2-1) surface member to the (2-2) surface member is a same as a direction in which the first electrode and the second electrode are spaced apart from each other.

19. A manufacturing method of a display device comprising:
patterning an alignment electrode including a first alignment electrode and a second alignment electrode on a base layer;
supplying ink including light emitting elements onto the base layer; and
aligning the light emitting elements between the first alignment electrode and the second alignment electrode, wherein
each of the light emitting elements includes:
end portions including a first end portion and a second end portion;
a side portion between the first end portion and the second end portion;
a semiconductor stacked member including a first semiconductor layer adjacent to the first end portion, a second semiconductor layer adjacent to the second end portion, and an active layer disposed between the first semiconductor layer and the second semiconductor layer;
a first surface member disposed on the side portion of each of the light emitting elements, the first surface member having a first surface energy, and
a second surface member the second surface member disposed on the end portions of each of the light emitting elements, second surface member having a second surface energy less than the first surface energy of the first surface member.

20. The manufacturing method of claim 19, wherein
each of the first surface member and the second surface member includes at least one material selected from a group consisting of a silane material, a phosphonate material, a carboxylate material, a catechol material, an alkyne material, an alkene material, and an amine material,
the first surface member includes a first functional group,
the second surface member includes a second functional group different from the first functional group,
the first functional group includes one of a hydroxyl group (—OH) and a carboxyl group (—COOH), and
the second functional group includes one of a methyl group (—CH3) and a fluorine group (—F).
